(19) United States
(12) Patent Application Publication
(10) Pub. No.: US 2026/0247639 A1
(43) Pub. Date: Aug. 20, 2026

(54) Capacitor, Array Of Memory Cells That Individually Comprise A Capacitor, Method Used In Forming A Capacitor, And Method Used In Forming An Array Of Memory Cells That Individually Comprise A Capacitor

(71) Applicant: Micron Technology, Inc., Boise, ID (US)

(72) Inventors: Clement Jacob, Boise, ID (US); Matthew N. Rocklein, Boise, ID (US); Jeffery B. Hull, Boise, ID (US); Richard Beeler, Boise, ID (US); Vassil N. Antonov, Boise, ID (US); Karine Paulette Pierrette Florent, Boise, ID (US); Ashonita A. Chavan, Boise, ID (US)

(73) Assignee: Micron Technology, Inc., Boise, ID (US)

(21) Appl. No.: 19/449,668

(22) Filed: Jan. 15, 2026

Related U.S. Application Data
(60) Provisional application No. 63/760,842, filed on Feb. 20, 2025.

(51) Int. Cl. H10D 1/68; H10B 12/00

(52) U.S. Cl. CPC H10D 1/696; H10B 12/03; H10B 12/30

(57) ABSTRACT

A capacitor comprises first and second conductive electrodes having a capacitor insulator there-between. One of the first and second conductive electrodes comprises: titanium oxynitride directly against the capacitor insulator; first titanium nitride directly against the titanium oxynitride; second titanium nitride directly against the first titanium nitride, a perceptible interface being between the first and second titanium nitrides, the second titanium nitride being thicker than the first titanium nitride; and a conductively-doped silicon and germanium-comprising material directly against the second titanium nitride. Other embodiments, including method, are disclosed.

### TECHNICAL FIELD

Embodiments disclosed herein pertain to capacitors, to arrays of memory cells that individually comprise a capacitor, to methods used in forming a capacitor, and to methods used in forming an array of memory cells that individually comprise a capacitor.

### BACKGROUND

Memory is one type of integrated circuitry and is used in computer systems for storing data. Memory may be fabricated in one or more arrays of individual memory cells. Memory cells may be written to, or read from, using digitlines (which may also be referred to as bitlines, data lines, or sense lines) and access lines (which may also be referred to as wordlines). The digitlines may conductively interconnect memory cells along columns of the array, and the access lines may conductively interconnect memory cells along rows of the array. Each memory cell may be uniquely addressed through the combination of a digitline and an access line.

Memory cells may be volatile, semi-volatile, or non-volatile. Non-volatile memory cells can store data for extended periods of time in the absence of power. Non-volatile memory is conventionally specified to be memory having a retention time of at least about 10 years. Volatile memory dissipates and is therefore refreshed/rewritten to maintain data storage. Volatile memory may have a retention time of milliseconds or less. Regardless, memory cells are configured to retain or store memory in at least two different selectable states. In a binary system, the states are considered as either a "0" or a "1”. In other systems, at least some individual memory cells may be configured to store more than two levels or states of information.

A capacitor is one type of electronic component that may be used in a memory cell. A capacitor has two electrical conductors separated by electrically insulating material. Energy as an electric field may be electrostatically stored within such material. Depending on composition of the insulator material, that stored field will be volatile or non-volatile. For example, a capacitor insulator material including only SiO₂ will be volatile. One type of non-volatile capacitor is a ferroelectric capacitor which has ferroelectric material as at least part of the insulating material. Ferroelectric materials are characterized by having two stable polarized states and thereby can comprise programmable material of a capacitor and/or memory cell. Other programmable materials may be used as a capacitor insulator to render capacitors non-volatile.

A field effect transistor is another type of electronic component that may be used in a memory cell. These transistors comprise a pair of conductive source/drain regions having a semiconductive channel region there-between. A conductive gate is adjacent the channel region and separated therefrom by a thin gate insulator. Application of a suitable voltage to the gate allows current to flow from one of the source/drain regions to the other through the channel region. When the voltage is removed from the gate, current is largely prevented from flowing through the channel region. Field effect transistors may also include additional structure, for example a reversibly programmable charge-storage region as part of the gate construction between the gate insulator and the conductive gate. Regardless, the gate insulator may be programmable, for example being ferroelectric.

Capacitors and field effect transistors can of course be used in other integrated circuitry not comprising memory circuitry.

### BRIEF DESCRIPTION OF THE DRAWINGS

FIG. 1 is a diagrammatic schematic of a DRAM memory array and peripheral circuitry in accordance with the prior art and in accordance with an embodiment of the invention.

FIG. 2 is an enlargement of a portion of FIG. 1.

FIG. 3 is a diagrammatic cross-sectional view of a capacitor in accordance with an embodiment of the invention.

FIGS. 4 and 5 are diagrammatic sequential cross-sectional views of a method used in forming a capacitor in accordance with some embodiments of the invention.

### DETAILED DESCRIPTION OF EXAMPLE EMBODIMENTS

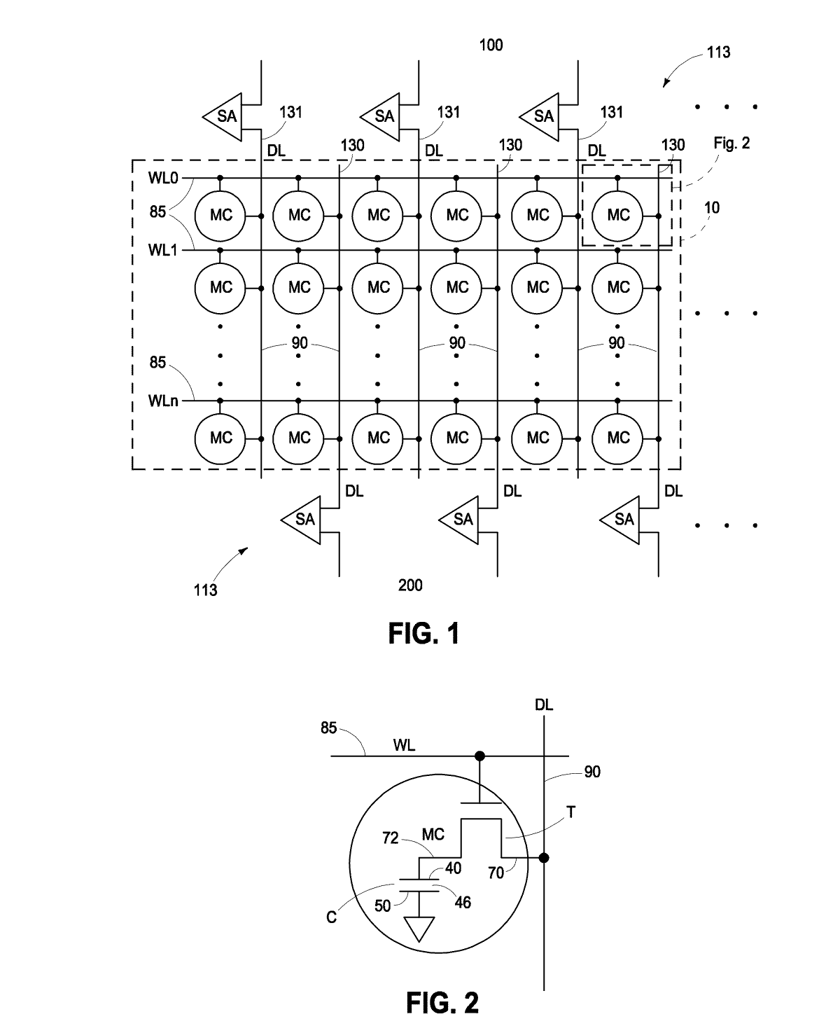

Embodiments of the invention include methods used in forming a capacitor, for example as may be used in memory or other integrated circuitry. Embodiments of the invention also encompass methods used in forming an array of memory cells that individually comprise a capacitor, for example DRAM circuitry. Embodiments of the invention also encompass a capacitor and an array of memory cells that individually comprise a capacitor independent of method of manufacture. Example embodiments are described with reference to FIGS. 1-5.

One example prior art schematic diagram of DRAM circuitry, and in accordance with an embodiment of the invention, is shown in FIGS. 1 and 2. FIG. 2 shows example memory cells MC individually comprising a transistor T comprising a pair of source/drain regions 70, 72 and a capacitor C comprising a second capacitor electrode 40, a first capacitor electrode 50, and a capacitor insulator 46 there-between. One electrode of capacitor C (e.g., 50) is directly electrically coupled to a suitable potential (e.g., ground) and the other capacitor electrode (e.g., 40) is contacted with or comprises one of the source/drain regions of transistor T (e.g., 72). The other source/drain region of transistor T (e.g., 70) is electrically coupled (e.g., directly) with a digitline 130 or 131 (also individually designated as DL). The gate of transistor T is directly electrically coupled with (e.g., comprises part of) a wordline WL. FIG. 1 shows digitlines 130 and 131 extending from one of opposite sides 100 and 200 of a memory array area 10 into a peripheral circuitry area 113 that is aside memory array area 10. Digitlines 130 and 131 individually directly electrically couple with a sense amp SA on opposite sides 100 and 200 of array area 10 within peripheral circuitry area 113. Accordingly, and in one embodiment, transistors T are arrayed in rows 85 and columns 90 and a gateline WL interconnects multiple of transistors T along individual of the rows. A digitline DL interconnects multiple of transistors T along individual of the columns. The memory cells may be array horizontally, vertically, or otherwise relative one another.

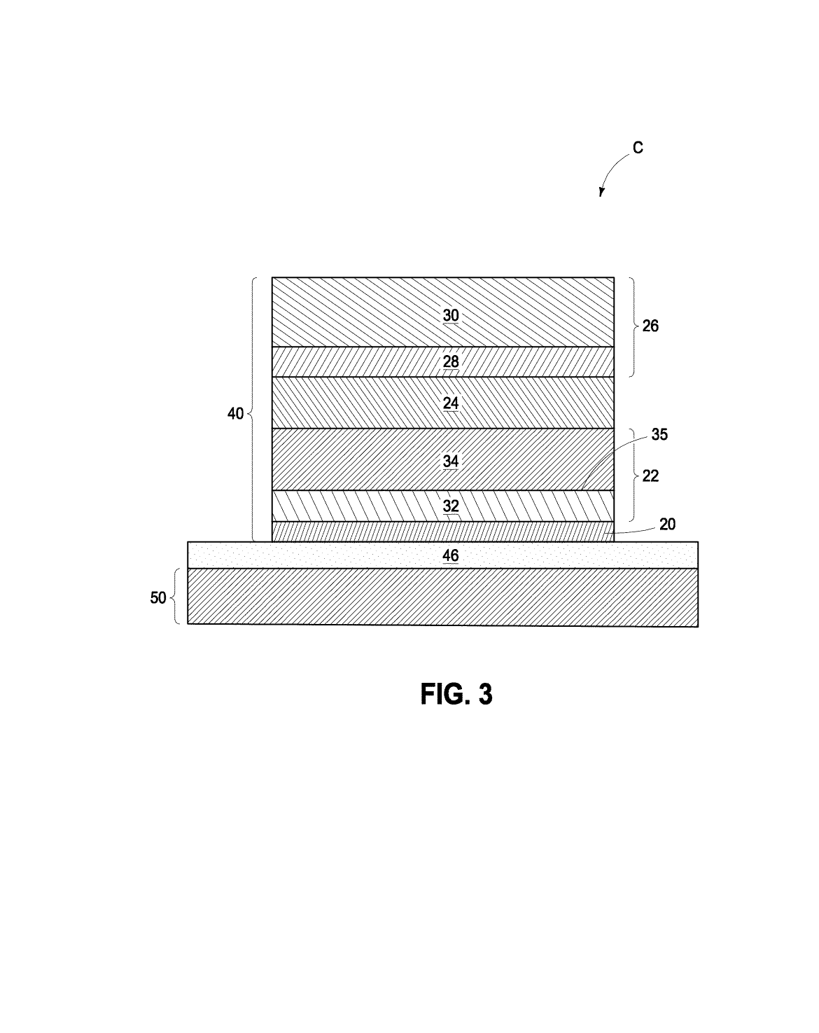

FIG. 3 shows an example capacitor C. Such comprises a first conductive electrode (e.g., 50; e.g., conductive metal material such as titanium nitride) and a second conductive electrode (e.g., 40) having a capacitor insulator there-between (e.g., 46; e.g., silicon dioxide, silicon nitride, high-k dielectric, and/or ferroelectric). One of the first and second conductive electrodes (e.g., 40) comprises:
a conductively-doped silicon and germanium-comprising material 24 directly against titanium nitride 22. one [at least one] of (a), (b), (c), (d), (e), and (f) directly against capacitor insulator 46, where:
   (a): platinum
   (b): iridium;
   (c): vanadium nitride;
   (d): vanadium oxynitride;
   (e): molybdenum nitride; and
   (f): molybdenum oxynitride;
titanium nitride 22 directly against one of the (a). the (b), the (c), the (d), the (e), and the (f), and
a conductively-doped silicon and germanium-comprising material 24 directly against titanium nitride 22.

In the figures, the one of the (a), the (b), the (c), the (d), the (e), and the (f) is designated with the numeral 20. In one embodiment, the one conductive electrode 40 of the first and second conductive electrodes comprises tungsten-comprising material 26 (e.g., tungsten nitride 28 under elemental tungsten 30) directly against conductively-doped silicon and germanium-comprising material 24. In one embodiment, the one (e.g., 40) of the first and second conductive electrodes comprises only one of the (a), the (b), the (c), the (d), the (e), and the (f) and, in another embodiment, comprises more than one of the (a), the (b), the (c), the (d), the (e), and the (f).

In one embodiment and as shown, titanium nitride 22 comprises first titanium nitride 32 directly against the one 20 of the (a), the (b), the (c), the (d), the (e) and the (f) and second titanium nitride 34 directly against first titanium nitride 32. A perceptible interface 35 is between first titanium nitride 32 and second titanium nitride 34 when both are present (e.g., even if such are identical in composition) and second titanium nitride 34 is thicker than first titanium nitride 32. In one such embodiment, chlorine is in each of first titanium nitride 32 and second titanium nitride 34, with more chlorine being in second titanium nitride 34 than is in first titanium nitride 32. In one such latter embodiment, first titanium nitride 32 has from 2 times to 100 times less chlorine than is in second titanium nitride 34. In one embodiment, first titanium nitride 32 has at least 5 times less chlorine than is in second titanium nitride 34 (e.g., 0.5 atomic percent chlorine in second titanium nitride 34 and 0.1 atomic percent chlorine in first titanium nitride 32).

Example thickness are as follows: 50: 100 Angstroms to 2,000 Angstroms; 46: 50 Angstroms to 250 Angstroms; 20: 10 Angstroms to 30 Angstroms; 32: 10 Angstroms to 20 Angstroms; 34: 30 Angstroms to 80 Angstroms; 24: 700 Angstroms to 1,300 Angstroms; 28: 700 Angstroms to 1,300 Angstroms; and 30: 600 Angstroms to 1,200 Angstroms. Either or each of capacitor electrodes 40 and 50 may comprise one or more of materials 20, 22, 24, and 26.

Any other attribute(s) or aspect(s) as shown and/or described herein with respect to other embodiments may be used with respect to the above-described embodiments.

In one embodiment, a capacitor (e.g., C) comprises first and second conductive electrodes (e.g., 50 and 40) having a capacitor insulator (e.g., 46) there-between. One of the first and second conductive electrodes (e.g., 40) comprises:
titanium oxynitride (e.g., 20) directly against capacitor insulator 46;
first titanium nitride (e.g., 32) directly against the titanium oxynitride;
second titanium nitride (e.g., 34) directly against first titanium nitride 32, with a perceptible interface (e.g., 35) being between first and second titanium nitrides 32 and 34, and with second titanium nitride 34 being thicker than first titanium nitride 32; and
a conductively-doped silicon and germanium-comprising material (e.g., 24) directly against second titanium nitride 34.
Any other attribute(s) or aspect(s) as shown and/or described herein with respect to other embodiments may be used.

Embodiments of the invention encompass methods used in forming a capacitor (e.g., C) including forming an array (e.g., 10) of memory cells (e.g., MC) that individually comprise one of the capacitors formed by the method. The method embodiments may incorporate, form, and/or have any of the attributes described with respect to device embodiments.

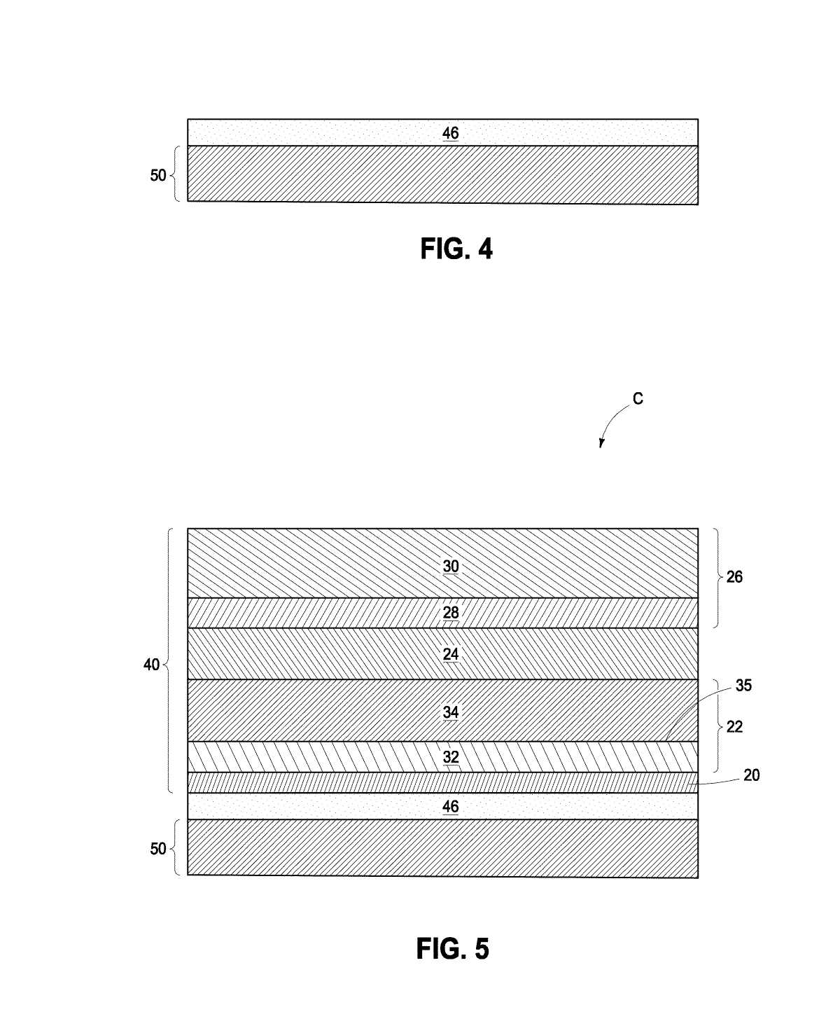

Referring to FIG. 4, a method used in forming a capacitor comprises forming conductive first capacitor electrode material 50, for example by atomic layer deposition (e.g., using advanced sequential flow deposition [ASFD] equipment available from Tokyo Electron Limited, US subsidiaries, 2400 Grove Boulevard Austin, Texas 78741). Capacitor insulator material 46 has been formed directly against first capacitor electrode material 50.

Referring to FIG. 5, conductive second capacitor electrode material 40 has been formed directly against capacitor insulator material 46. The forming of second capacitor electrode material 40 comprises:
forming one 20 [at least one] of (a), (b), (c), (d), (e), (f), and (g) directly against capacitor insulator material 40, where:
   (a): platinum
   (b): iridium;
   (c): vanadium nitride;
   (d): vanadium oxynitride;
   (e): molybdenum nitride;
   (f): molybdenum oxynitride; and
   (g): titanium oxynitride
forming titanium nitride 22 directly against the one 20 of the (a), the (b), the (c), the (d), the (e), the (f), and the (g); and
forming a conductively-doped silicon and germanium-comprising material 24 directly against titanium nitride 22.

In one embodiment and as shown, a tungsten-comprising material 26 has been formed directly against conductively-doped silicon and germanium-comprising material 24.

In one embodiment, the forming of titanium nitride 22 comprises atomic layer deposition [e.g., by ASFD] and in one embodiment comprises chemical vapor deposition (CVD) in a CVD furnace. Example conditions for each are 320°C to 420°C, 0.2 Torr to 10 Torr, and using TiCl₄ and NH₃ as precursors.

In one embodiment, the forming of titanium nitride 22 comprises CVD in a CVD furnace to form first titanium nitride 32. This is followed by atomic layer deposition [e.g., by ASFD] of second titanium nitride 34 directly onto first titanium nitride 32 (an interface 35 being there-between). In one such embodiment, chlorine is formed in each of first titanium nitride 32 and second titanium nitride 34 (e.g., as a result of using TiCl₄ as a titanium-source precursor), with more chlorine being formed in second titanium nitride 34 than in first titanium nitride 32. Regardless, conductively-doped silicon and germanium-comprising material 24 is formed directly against second titanium nitride 34.

Materials 50, 46, 20, 22, 24, and/or 26 may be patterned together and/or separately relative one another (not shown) to form any desired capacitor shape.

Any other attribute(s) or aspect(s) as shown and/or described herein with respect to other embodiments may be used.

A main challenge with capacitors is achieving high capacitance while controlling leakage. Typically, cell optimizations that improve capacitance proportionally increase leakage. Capacitors having one (at least one) electrode having the attributes described and claimed herein have been shown to increase work function by 8% over previous capacitor electrodes and thereby reduce leakage while maintaining or increasing capacitance for the same capacitor insulator material and thickness.

The above processing(s) or construction(s) may be considered as being relative to an array of components formed as or within a single stack or single deck of such components above or as part of an underlying base substrate (albeit, the single stack/deck may have multiple tiers). Control and/or other peripheral circuitry for operating or accessing such components within an array may also be formed anywhere as part of the finished construction, and in some embodiments may be under the array (e.g., CMOS under-array). Regardless, one or more additional such stack(s)/deck(s) may be provided or fabricated above and/or below that shown in the figures or described above. Further, the array(s) of components may be the same or different relative one another in different stacks/decks and different stacks/decks may be of the same thickness or of different thicknesses relative one another. Intervening structure may be provided between immediately-vertically-adjacent stacks/decks (e.g., additional circuitry and/or dielectric layers). Also, different stacks/decks may be electrically coupled relative one another. The multiple stacks/decks may be fabricated separately and sequentially (e.g., one atop another), or two or more stacks/decks may be fabricated at essentially the same time.

The circuitry described herein (e.g., conductive vias thereof) may connect with circuitry that is on either the top or the bottom (i.e., either z-axis side) of a vertical stack regardless of orientation of the construction in three-dimensional space and which is not material to aspects of the inventions disclosed herein. For example, and by way of example only, conductive vias may connect with peripheral control circuitry that is beneath the stack with respect to the orientation shown in the drawings. As an alternate example, and by way of example only, conductive vias may connect with peripheral control circuitry that is above the stack with respect to the shown orientation, for example to another substrate having such circuitry and that is bonded with the top of the stack with respect to the shown orientation. In such alternate example, the construction may be inverted from the shown orientation and then bonded with the other substrate. Further, in such alternate example, electronic components may be fabricated relative to the bottom of the stack with respect to the shown orientation but inverted therefrom during processing. Such electronic components may connect with conductive vias that extend through the stack to the substrate bonded with the other side that has such peripheral control circuitry. Regardless, constructions as shown and described herein may be processed, packaged, and/or mounted in any three-dimensional spatial orientation.

The assemblies and structures discussed above may be used in integrated circuits/circuitry and may be incorporated into electronic systems. Such electronic systems may be used in, for example, memory modules, device drivers, power modules, communication modems, processor modules, and application-specific modules, and may include multilayer, multichip modules. The electronic systems may be any of a broad range of systems, such as, for example, cameras, wireless devices, displays, chip sets, set top boxes, games, lighting, vehicles, clocks, televisions, cell phones, personal computers, automobiles, industrial control systems, aircraft, etc.

In this document unless otherwise indicated, “elevational”, “higher”, “upper”, “lower”, “top”, “atop”, “bottom”, “above”, “below”, “under”, “beneath”, “up”, and “down” are generally with reference to the vertical direction. “Horizontal” refers to a general direction (i.e., within 10 degrees) along a primary substrate surface and may be relative to which the substrate is processed during fabrication, and vertical is a direction generally orthogonal thereto. Reference to “exactly horizontal” is the direction along the primary substrate surface (i.e., no degrees there-from) and may be relative to which the substrate is processed during fabrication and as shown in drawings (if any) herein. Further, “vertical” and “horizontal” as used herein are generally perpendicular directions relative one another and independent of orientation of the substrate in three-dimensional space during fabrication and/or in a finished construction. Additionally, “elevationally-extending” and “extend(ing) elevationally” refer to a direction that is angled away by at least 45° from exactly horizontal. Further, “extend(ing) elevationally”, “elevationally-extending”, “extend(ing) horizontally”, “horizontally-extending” and the like with respect to a field effect transistor are with reference to orientation of the transistor’s channel length along which current flows in operation between the source/drain regions. For bipolar junction transistors, “extend(ing) elevationally” “elevationally-extending”, “extend(ing) horizontally”, “horizontally-extending” and the like, are with reference to orientation of the base length along which current flows in operation between the emitter and collector. In some embodiments, any component, feature, and/or region that extends elevationally extends vertically or within 10° of vertical.

Further, “directly above”, “directly below”, and “directly under” require at least some lateral overlap (i.e., horizontally) of two stated regions/materials/components relative one another. Also, use of “above” not preceded by “directly” only requires that some portion of the stated region/material/component that is above the other be elevationally outward of the other (i.e., independent of whether there is any lateral overlap of the two stated regions/materials/components). Analogously, use of “below” and “under” not preceded by “directly” only requires that some portion of the stated region/material/component that is below/under the other be elevationally inward of the other (i.e., independent of whether there is any lateral overlap of the two stated regions/materials/components).

Any of the materials, regions, and structures described herein may be homogenous or non-homogenous, and regardless may be continuous or discontinuous over any material which such overlie. Where one or more example composition(s) is/are provided for any material, that material may comprise, consist essentially of, or consist of such one or more composition(s). Further, unless otherwise stated, each material may be formed using any suitable existing or future-developed technique, with atomic layer deposition, chemical vapor deposition, physical vapor deposition, epitaxial growth, diffusion doping, and ion implanting being examples.

Additionally, “thickness” by itself (no preceding directional adjective) is defined as the mean straight-line distance through a given material or region perpendicularly from a closest surface of an immediately-adjacent material of different composition or of an immediately-adjacent region. Additionally, the various materials or regions described herein may be of substantially constant thickness or of variable thicknesses. If of variable thickness, thickness refers to average thickness unless otherwise indicated, and such material or region will have some minimum thickness and some maximum thickness due to the thickness being variable. As used herein, “different composition” only requires those portions of two stated materials or regions that may be directly against one another to be chemically and/or physically different, for example if such materials or regions are not homogenous. If the two stated materials or regions are not directly against one another, “different composition” only requires that those portions of the two stated materials or regions that are closest to one another be chemically and/or physically different if such materials or regions are not homogenous. In this document, a material, region, or structure is “directly against” another when there is at least some physical touching contact of the stated materials, regions, or structures relative one another. In contrast, “over”, “on”, “adjacent”, “along”, and “against” not preceded by “directly” encompass “directly against” as well as construction where intervening material(s), region(s), or structure(s) result(s) in no physical touching contact of the stated materials, regions, or structures relative one another.

Herein, regions-materials-components are “electrically coupled” relative one another if in normal operation electric current is capable of continuously flowing from one to the other and does so predominately by movement of subatomic positive and/or negative charges when such are sufficiently generated. Another electronic component may be between and electrically coupled to the regions-materials-components. In contrast, when regions-materials-components are referred to as being "directly electrically coupled”, no intervening electronic component (e.g., no diode, transistor, resistor, transducer, switch, fuse, etc.) is between the directly electrically coupled regions-materials-components.

Any use of “row” and “column” in this document is for convenience in distinguishing one series or orientation of features from another series or orientation of features and along which components have been or may be formed. “Row” and “column” are used synonymously with respect to any series of regions, components, and/or features independent of function. Regardless, the rows may be straight and/or curved and/or parallel and/or not parallel relative one another, as may be the columns. Further, the rows and columns may intersect relative one another at 90° or at one or more other angles (i.e., other than the straight angle).

The composition of any of the conductive/conductor/conducting materials herein may be conductive metal material and/or conductively-doped semiconductive/semiconductor/semiconducting material. “Metal material” is any one or combination of an elemental metal, any mixture or alloy of two or more elemental metals, and any one or more metallic compound(s).

Herein, any use of “selective” as to etch, etching, removing, removal, depositing, forming, and/or formation is such an act of one stated material relative to another stated material(s) so acted upon at a rate of at least 2:1 by volume. Further, any use of selectively depositing, selectively growing, or selectively forming is depositing, growing, or forming one material relative to another stated material or materials at a rate of at least 2:1 by volume for at least the first 75 Angstroms of depositing, growing, or forming.

Unless otherwise indicated, use of “or” herein encompasses either and both.

### Conclusion

In some embodiments, a capacitor comprises first and second conductive electrodes having a capacitor insulator there-between. One of the first and second conductive electrodes comprises:
one of (a), (b), (c), (d), (e), and (f) directly against the capacitor insulator, where:
   (a): platinum
   (b): iridium;
   (c): vanadium nitride;
   (d): vanadium oxynitride;
   (e): molybdenum nitride; and
   (f): molybdenum oxynitride;

Titanium nitride is directly against the one of the (a), the (b), the (c), the (d), the (e), and the (f). A conductively-doped silicon and germanium-comprising material is directly against the titanium nitride.

In some embodiments, a capacitor comprises first and second conductive electrodes having a capacitor insulator there-between. One of the first and second conductive electrodes comprises titanium oxynitride directly against the capacitor insulator. First titanium nitride is directly against the titanium oxynitride. Second titanium nitride is directly against the first titanium nitride. A perceptible interface is between the first and second titanium nitrides. The second titanium nitride is thicker than the first titanium nitride. A conductively-doped silicon and germanium-comprising material is directly against the second titanium nitride.

In some embodiments, a method used in forming a capacitor comprises forming conductive first capacitor electrode material. Capacitor insulator material is formed directly against the first capacitor electrode material. Conductive second capacitor electrode material is formed directly against the capacitor insulator material. The forming of the second capacitor electrode comprises:
forming one of (a), (b), (c), (d), (e), (f), and (g) directly against the capacitor insulator material, where:
   (a): platinum
   (b): iridium;
   (c): vanadium nitride;
   (d): vanadium oxynitride;
   (e): molybdenum nitride;
   (f): molybdenum oxynitride; and
   (g): titanium oxynitride

Titanium nitride is formed directly against the one of the (a), the (b), the (c), the (d), the (e), the (f), and the (g). A conductively-doped silicon and germanium-comprising material is formed directly against the titanium nitride.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

1. A capacitor comprising:
first and second conductive electrodes having a capacitor insulator there-between; and
one of the first and second conductive electrodes comprising:
one of (a), (b), (c), (d), (e), and (f) directly against the capacitor insulator, where:
(a): platinum
(b): iridium;
(c): vanadium nitride;
(d): vanadium oxynitride;
(e): molybdenum nitride; and
(f): molybdenum oxynitride;
titanium nitride directly against the one of the (a), the (b), the (c), the (d), the (e), and the (f); and
a conductively-doped silicon and germanium-comprising material directly against the titanium nitride.

2. The capacitor of claim 1 wherein the one of the first and second conductive electrodes comprises only one of the (a), the (b), the (c), the (d), the (e), and the (f).

3. The capacitor of claim 1 wherein the one of the first and second conductive electrodes comprises more than one of the (a), the (b), the (c), the (d), the (e), and the (f).

4. The capacitor of claim 1 wherein the one of the (a), the (b), the (c), the (d), the (e), and the (f) is at least the (a).

5. The capacitor of claim 1 wherein the one of the (a), the (b), the (c), the (d), the (e), and the (f) is at least the (b).

6. The capacitor of claim 1 wherein the one of the (a), the (b), the (c), the (d), the (e), and the (f) is at least the (c).

7. The capacitor of claim 1 wherein the one of the (a), the (b), the (c), the (d), the (e), and the (f) is at least the (d).

8. The capacitor of claim 1 wherein the one of the (a), the (b), the (c), the (d), the (e), and the (f) is at least the (e).

9. The capacitor of claim 1 wherein the one of the (a), the (b), the (c), the (d), the (e), and the (f) is at least the (f).

10. The capacitor of claim 1 wherein the titanium nitride comprises:
first titanium nitride directly against the one of the (a), the (b), the (c), the (d), the (e) and the (f); and
second titanium nitride directly against the first titanium nitride, a perceptible interface being between the first and second titanium nitrides, the second titanium nitride being thicker than the first second titanium nitride.

11. The capacitor of claim 10 comprising chlorine in each of the first and second titanium nitrides, more chlorine being in the second titanium nitride than in the first titanium nitride.

12. The capacitor of claim 11 wherein the first titanium nitride has at least 5 times less chlorine than is in the second titanium nitride.

13. The capacitor of claim 11 wherein the first titanium nitride has from 2 times to 100 times less chlorine than is in the second titanium nitride.

14. The capacitor of claim 1 wherein the one of the first and second conductive electrodes comprises tungsten-comprising material directly against the conductively-doped silicon and germanium-comprising material.

15. An array of memory cells that individually comprise the capacitor of claim 1.

16. A capacitor comprising:
first and second conductive electrodes having a capacitor insulator there-between; and
one of the first and second conductive electrodes comprising:
titanium oxynitride directly against the capacitor insulator; first titanium nitride directly against the titanium oxynitride;
second titanium nitride directly against the first titanium nitride, a perceptible interface being between the first and second titanium nitrides, the second titanium nitride being thicker than the first titanium nitride; and
a conductively-doped silicon and germanium-comprising material directly against the second titanium nitride.

17. The capacitor of claim 16 comprising chlorine in each of the first and second titanium nitrides, more chlorine being in the second titanium nitride than in the first titanium nitride.

18. The capacitor of claim 16 wherein the first titanium nitride has at least 5 times less chlorine than is in the second titanium nitride.

19. The capacitor of claim 16 wherein the first titanium nitride has from 2 times to 100 times less chlorine than is in the second titanium nitride.

20. The capacitor of claim 16 wherein the one of the first and second conductive electrodes comprises tungsten-comprising material directly against the conductively-doped silicon and germanium-comprising material.
